(19) United States
(12) Patent Application Publication
(10) Pub. No.: US 2007/0139874 A1
(43) Pub. Date: Jun. 21, 2007

(54) Detachable handle for notebook computers

(76) Inventor: Eiichi Tanaka, Cupertino, CA (US)

Correspondence Address: SHEPPARD, MULLIN, RICHTER & HAMPTON LLP, 333 SOUTH HOPE STREET, 48TH FLOOR, LOS ANGELES, CA, 90071-1448, US

(21) Appl. No.: 11/300,944

(22) Filed: Dec. 15, 2005

(51) Int. Cl. G06F 1/16; H05K 5/00

(52) U.S. Cl. 361/683; 361/679

(57) ABSTRACT

A system for carrying a notebook computer without a case is disclosed. The system comprises a computer that has two slots of the type which receive a locking mechanism on an edge surface, and a handle having a strap with attachment mechanisms at the ends thereof that are adapted to detachably and securely mate with the slots on the computer. When the handle is attached it can be used to carry the computer.

### FIELD OF THE INVENTION

The present invention is directed to means for carrying notebook computers, and is particularly related to a detachable carrying handle.

### BACKGROUND OF THE INVENTION

An essential feature of notebook computers is the ease with which they may be transported, allowing the computers to be used in a variety of ways at a variety of different locations. Typically a notebook computers is transported in a carrying case, which may specially designed for transporting notebook computers, or which may simply be a user's briefcase. However, there are situations where the user would like to transport a notebook computer without using a carrying case. In such situations it is important that the unprotected computer be securely held in a convenient manner to avoid the risk of damage.

### SUMMARY OF THE INVENTION

Accordingly, the present invention is generally directed to a detachable handle for carrying a notebook computer. In one aspect, the present invention is directed to a notebook computer system, comprising a computer body having an elongate edge surface, the edge surface having at least two spaced apart slots adapted to receive locking mechanisms therein, and a detachable handle comprising a strap having attachment mechanisms disposed at the ends thereof, each of said attachment mechanisms mating with one of said slots, such that said handle can be removably and securely attached to said computer body. The edge surface may be near the rear surface of the computer body. Preferably, the strap has a length of between about eight and about twelve inches, and comprises an ergonomic hand grip. In another aspect, at least one of the attachment mechanisms can be locked, and the strap can be used to lock the computer body in place. In this aspect, the strap preferably comprises a metal cable. Preferably, both of said attachment mechanisms can be locked.

In another aspect, the present invention is directed to a handle for use with a notebook computer, the notebook computer having an edge surface with at least two spaced apart slots adapted to receive locking mechanisms therein, the handle comprising a strap, and an attachment mechanism disposed on each end of said strap, each of the attachment mechanisms being adapted for insertion into the slots on the computer, such that the handle can be removably and securely attached to the notebook computer. Preferably at least one of the attachment mechanisms can be locked to the computer, and more preferably, both of the attachment mechanisms can be locked to said computer. The strap may comprise a metal cable, and may comprise an ergonomic hand grip. Preferably, the strap has a length of between about eight and about twelve inches.

In yet another aspect, the present invention is directed to a notebook computer having at least two substantially identical slots for receiving attachment mechanisms disposed on the ends of a handle, the slots being symmetrically positioned on an edge surface of said notebook computer. Preferably, the slots are more than six inches apart and are positioned on the rear edge of the computer.

### BRIEF DESCRIPTION OF THE DRAWINGS

The foregoing aspects and the attendant advantages of this invention will become more readily apparent by reference to the following detailed description when taken in conjunction with the accompanying drawings, wherein:

FIG. 1 is a depiction of a notebook computer in accordance with an embodiment of the present invention.

FIG. 2 is a depiction of a detachable handle for a notebook computer in accordance with an embodiment of the present invention.

FIG. 3 is a depiction of a notebook computer system in accordance with an embodiment of the present invention.

### DETAILED DESCRIPTION

In the following description, numerous specific details are set forth to provide a more thorough description of specific embodiments of the invention. It will be apparent, however, to those skilled in the art, that the invention may be practiced without all the specific details given below. Consistent numbering is used in the Figures.

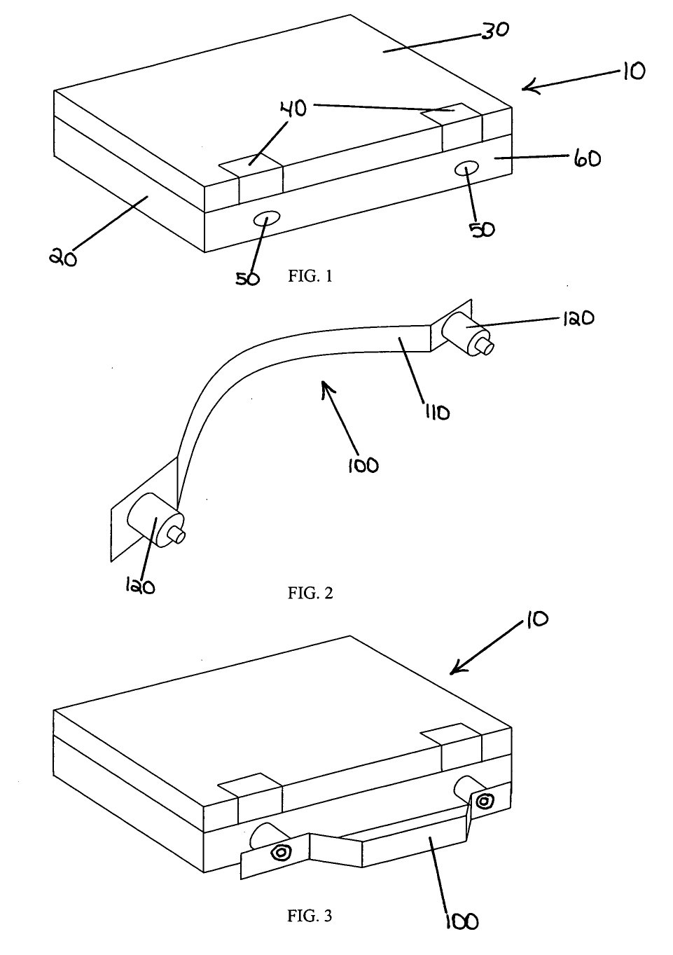

FIG. 1 depicts a notebook computer 10 in accordance with an embodiment of the present invention. As used herein, the term notebook computer is intended in its broadest sense to mean all types of portable computing devices, including, but not limited to, notebook, laptop, tablet and convertible computers. Computer 10 comprises a lower or base portion 20 and an upper or display portion 30, which are connected by one or more hinges 40 that allow the computer to be opened for operation thereof or closed for storage and transport. A typical notebook computer does not have any handle or other structure to facilitate easy carrying. Accordingly, in the prior art a notebook computer would be carried by the user by placing computer in some type of carrying case or briefcase, or by simple gripping it in the user's hands. This later approach is inconvenient and somewhat risky insofar as the computer is relatively bulky and not easily gripped.

As further depicted in FIG. 1, computer 10 also comprises two slots 50 on the rear edge surface of base portion 20. Each of the slots are designed to receive a locking mechanism. Unfortunately, the high portability of notebook computers has made computer theft a concern, and the use of a single such slot on a notebook computer to provide a locking structure has become relatively common in order to allow users to secure their computer to an immobile object such as a desk.

Locking systems that rely on slots in notebook computers are widely sold, for example, by Kensington Microware Limited of San Mateo, Calif. (“Kensington”) and are described, for example, in U.S. Pat. Nos. 5,327,752; 5,381,685; and 5,502,989, all of which are assigned to Kensington, the disclosures of which are incorporated by reference. Such locking mechanisms will be referred to as “Kensington” locks.

A Kensington lock comprises a T-shaped attachment mechanism mounted on a spindle that is connected to a lock that is used to rotate or prevent rotation of the spindle. The attachment mechanism is inserted into the slot and rotated using a key, such that the bar which forms the top of the “T” can no longer move in and out of the slot. In a preferred embodiment of the present invention, slots 50 are both adapted to received Kensington locks, and either of them can be used in a known fashion to receive a locking device to prevent computer theft. Preferably, slots 50 are spaced apart by at least six inches, and are symmetrically disposed on the rear surface of the computer, near opposing ends thereof so that the computer is substantially balanced when the handle, described next, is used. Alternatively, the slots may be positioned on the side surfaces of the computer.

Turning to FIG. 2, a detachable handle 100 for transporting a notebook computer is shown. Handle 100 comprises a strap 110 with attachment mechanisms 120 disposed at the ends thereof. Attachment mechanisms 120 are designed to mate with slots 50, so that handle 100 can be securely but detachably fastened to computer 10, as depicted in FIG. 3. In one embodiment, attachment mechanisms 120 comprise locks, such as Kensington locks, so that handle 100 can be securely locked to computer 10. However, it is not necessary for the attachment mechanisms to lock so long as they securely held in position without risk of becoming inadvertently detached from computer 10.

Preferably, handle 100 comprises a hand grip that is ergonomically designed so that it is easy and comfortable to grip. To this end, strap 110 may comprise an outer surface of leather or other soft, flexible material that is comfortable to handle. Preferably, handle 100 is between about eight and about twelve inches long. Alternatively, handle 100 may be substantially longer for use as a shoulder strap.

In an alternative embodiment of the present invention, handle 100 also serve as a theft preventive locking device. In such an embodiment, at least one of attachment mechanisms 120 is lockable, and strap 110 comprises a metal cable that is highly resistant to cutting. Such a metal cable can be embedded within a more comfortable material, such as leather or a synthetic fabric, that is more pleasant to grip. In this embodiment, when handle 100 serves as a locking device, one end of strap 110 is locked to the computer and the other end is locked, directly or indirectly, to an immobile object.

The embodiments described above are illustrative of the present invention and are not intended to limit the scope of the invention to the particular embodiments described. Accordingly, while one or more embodiments of the invention have been illustrated and described, it will be appreciated that various changes can be made therein without departing from the spirit or essential characteristics thereof. Accordingly, the disclosures and descriptions herein are not intended to be limiting of the scope of the invention, which is set forth in the following claims.

What is claimed is:

1. A notebook computer system, comprising:
a computer body having an elongate edge surface, said edge surface having at least two spaced apart slots adapted to receive locking mechanisms therein,
a detachable handle comprising a strap having attachment mechanisms disposed at the ends thereof, each of said attachment mechanisms mating with one of said slots, such that said handle can be removably and securely attached to said computer body.

2. The notebook computer system of claim 1, wherein said edge surface is the rear surface of the computer body.

3. The notebook computer system of claim 1 wherein said strap has a length of between about eight and about twelve inches.

4. The notebook computer system of claim 1 wherein at least one of said attachment mechanisms can be locked.

5. The notebook computer system of claim 1 wherein said strap comprises a hand grip.

6. The notebook computer system of claim 1 wherein said strap can be used to lock said computer body in place.

7. The notebook computer system of claim 6 wherein said strap comprises a metal cable.

8. The notebook computer system of claim 1 wherein both of said attachment mechanisms can be locked.

9. A handle for use with a notebook computer, said notebook computer having an edge surface with at least two spaced apart slots adapted to receive locking mechanisms therein, said handle comprising:
a strap,
an attachment mechanism disposed on each end of said strap, each of said attachment mechanisms being adapted for insertion into the slots on the computer, such that the handle can be removably and securely attached to said notebook computer.

10. The handle of claim 9 wherein at least one of said attachment mechanisms can be locked to said computer.

11. The handle of claim 10 wherein both of said attachment mechanisms can be locked to said computer.

12. The handle of claim 10 wherein said strap comprises a metal cable.

13. The handle of claim 9 wherein said strap comprises an ergonomic hand grip.

14. The handle of claim 9 wherein said strap has a length of between about eight and about twelve inches.

15. A notebook computer comprising at least two substantially identical slots for receiving attachment mechanisms disposed on the ends of a handle, said slots being symmetrically positioned on an edge surface of said notebook computer.

16. The notebook computer of claim 15, wherein said slots are more than six inches apart.

17. The notebook computer of claim 15 wherein said slots are positioned on the rear edge of the computer.
